(19) United States
(12) Patent Application Publication
(10) Pub. No.: US 2009/0123640 A1
(43) Pub. Date: May 14, 2009

(54) PRETREATMENT APPARATUS AND METHOD FOR WINDOW GLASS ADHESIVE COATING

(75) Inventor: Yasuo Suzuki, Tokyo (JP)

Correspondence Address: RANKIN, HILL & CLARK LLP, 38210 Glenn Avenue, WILLOUGHBY, OH, 44094-7808, US

(73) Assignee: HONDA MOTOR CO., LTD., Tokyo (JP)

(21) Appl. No.: 11/813,634

(22) PCT Filed: Jan. 11, 2006
(86) PCT No.: PCT/JP2006/300164

§ 371 Date: Jul. 10, 2007

(30) Foreign Application Priority Data
Jan. 14, 2005 (JP) 2005-008167

(51) Int. Cl. C23C 16/52; B05C 11/00

(52) U.S. Cl. 427/8; 118/712

(57) ABSTRACT

An apparatus for conducting pretreatment such as primer coating an adhesive coating surface of a window glass using a robot includes a degreasing device for removing dust and oil adhering to the adhesive coating surface and coating the adhesive coating surface with a degreasing solution; a primer coating device for coating the adhesive coating surface with primer, after that surface has been degreased by the degreasing device; and a primer inspection and determination device for inspecting the primer coated condition provided by the primer coating device to determine whether the coated condition is good or bad. The degreasing device includes a felt member for removing dust and oil adhering to the adhesive coating surface and coating the adhesive coating surface with the degreasing solution; a felt maintaining mechanism for maintaining the felt member; and a felt regenerating device for regenerating the felt member maintained by the felt maintaining mechanisms.

### BACKGROUND OF THE INVENTION

1. Field of the Invention

The present invention relates to a pretreatment apparatus for window glass adhesive coating, which can carry out degreasing, primer coating and the like on an adhesive coating surface of the window glass before coating the adhesive coating surface with an adhesive agent, and a method for the pretreatment.

2. Description of the Prior Art

In a conventional automobile body assembly process, in the case where a window glass is secured to an opening of the automobile body using an adhesive agent, prior to coating a peripheral section of the window glass with the adhesive agent, as a pretreatment process for an adhesive coating surface, the adhesive coating surface of the window glass is degreased in advance using a cloth and the like infiltrated with white gasoline and the like and then, a primer as an adhesive assistant is automatically coated on the adhesive coating surface by a robot and the like to increase the affinity of the adhesive agent for the window glass.

In coating work of this type, there is a case where coating failure such as a thin spot or skip is caused because the primer has fast-curing properties. If the window glass is conveyed to an adhesive process for an automobile body in such a coating failure condition, there is a possibility that an adhesive failure relating to the body is caused due to insufficient adhesive strength of the window glass. Thus, after coating with the primer, it is necessary for an operator to visually inspect the primer coated condition before conveying the window glass to the adhesive process and recoat a faulty point, if found, with the primer. In this manner, there is a problem in that the primer coating process can not be automated. There is another problem in that much installation space is required because the pretreatment process for the adhesive coating surface consists of a degreasing step, a primer-coating step, a primer-coating inspection step and the like.

From these problems, a pretreatment method for an adhesive coating surface, whereby a robot arm end is provided with a vertically movable wipe head and a primer coating gun in parallel for conducting a wipe treatment and primer coating operation within the same process using a single robot, is disclosed (Patent Document 1).

Also, a technique, whereby a reflective photoelectric sensor is secured to a primer coating device to detect the coated surface condition immediately after coating, is disclosed (Patent Document 2).

Further, a technique, whereby a laser beam is irradiated from one side of a primer coating surface, and on the other side thereof, a light and dark contrast of the primer coating surface formed through the transmission of the laser beam is captured to digitalize, thereby integrating the number of picture elements (pixels) for each predetermined range of the coated section, is disclosed (Patent Document 3).

Patent Document 1: Japanese Patent No. 2848115

Patent Document 2: Japanese Utility Model Publication No. 5-41808

Patent Document 3: Japanese Patent Publication No. 7-119584

However, in the pretreatment method for an adhesive coating surface as disclosed in Patent Document 1, an additional process must be provided for inspecting the primer coated condition, wherein the primer coated condition is inspected visually or by using an inspection device and the like. In the case where coating failure is found, an operator is required to recoat the faulty points. Thus, there is a problem in that the pretreatment cannot be automated. Also, in the case where the wipe head is tainted with dust, oil and the like after repeated use, since a wipe gun for wipe processing must be removed from a robot arm end to clean up the wipe head or to replace it with a new wipe head, handling is troublesome. There is also a problem in that the installation space for the pretreatment process becomes large.

Further, referring to the technique disclosed in Patent Document 2, in the case where the coating failure is found, an operator must recoat the faulty points, and a process for degreasing prior to primer coating is separately required. In this manner, there is a problem in that the installation space for pretreatment becomes large.

Still further, even in the technique disclosed in Patent Document 3, if the coating failure is found, the operator has to recoat the faulty points. It is also necessary to separately provide the degreasing and primer coating processes. Thus, there is a problem in that the installation space for pretreatment becomes large.

### SUMMARY OF THE INVENTION

It is therefore an object of the present invention to provide a pretreatment apparatus for window glass adhesive coating, which can solve the problems stated above and fully automate a degreasing process and a primer coating process for an adhesive coating surface, an inspection process of a primer coated condition and the like using a single robot, and to provide a method for the pretreatment.

In order to attain this object, according to a first aspect of the present invention, an apparatus for conducting pretreatment such as primer coating onto an adhesive coating surface of window glass using a robot comprises: a degreasing means for removing dust and oil adhering to the adhesive coating surface and coating the adhesive coating surface with a degreasing solution; a primer coating means for coating the adhesive coating surface, coated with the degreasing solution by the degreasing means, with primer; and a primer inspection and determination means for inspecting the primer coated condition coated by the primer coating means to determine whether the coated condition is good or bad.

According to a second aspect of the present invention, in the pretreatment apparatus for window glass adhesive coating according to the first aspect, the degreasing means comprises: a felt member for removing dust and oil adhering to the adhesive coating surface and coating the adhesive coating surface with a degreasing solution; a felt maintaining mechanism for maintaining the felt member; and a felt regenerating mechanism for regenerating the felt member maintained by the felt maintaining mechanism.

According to a third aspect of the present invention, in the pretreatment apparatus for window glass adhesive coating according to the second aspect, the felt regenerating mechanism comprises: a felt holding mechanism for holding a front end section of the felt member therebetween; a felt projection mechanism for projecting the felt member by a predetermined length in a condition in which the front end section of the felt member is held by the felt holding mechanism; and a cutting mechanism for cutting the front end section of the felt member projected by the felt projection mechanism.

According to a fourth aspect of the present invention, a pretreatment method for coating an adhesive coating surface of window glass with primer comprises the steps of: degreasing for removing dust and oil adhering to the adhesive coating surface and coating the adhesive coating surface with a degreasing solution; coating the adhesive coating surface processed in the degreasing step, with the primer; inspecting the primer coated condition coated in the primer coating step; and determining whether the primer coated condition is good or bad based on the inspection results in the primer inspection step.

According to a fifth aspect of the present invention, in the pretreatment method for window glass adhesive coating according to the fourth aspect, the primer inspection step comprises the steps of: coating with the primer in the primer coating step and simultaneously inspecting the primer coated condition at a linear section; inspecting the primer coated condition at a corner section; and determining whether the primer coated condition is good or bad based on the inspection results.

According to a sixth aspect of the present invention, in the pretreatment method for window glass adhesive coating according to the fourth aspect or the fifth aspect, in the case where the primer coated condition is determined to be bad in the determination step, the pretreatment method comprises the steps of: recoating a faulty point with the primer; re-inspecting the primer recoated condition; and re-determining whether the primer coated condition is good or bad based on the re-inspection results.

### BRIEF DESCRIPTION OF THE DRAWINGS

The above and other objects, features and advantages of the present invention will become more apparent from the following description when taken in conjunction with the accompanying drawings.

FIG. 1 is a view explaining a process to which a pretreatment apparatus for window glass adhesive coating and a method for the pretreatment according to the present invention are applied;

FIG. 2 is a front view of the pretreatment apparatus for window glass adhesive coating according to the present invention;

FIG. 3 is a side view of the pretreatment apparatus for window glass adhesive coating according to the present invention;

FIG. 4 is a side view of a felt holding mechanism and a cutting mechanism;

FIG. 5 is cross-sectional view taken along line A-A of FIG. 4;

FIG. 6 is a plan view of the felt holding mechanism and the cutting mechanism, with a partial cross section;

FIGS. 7(a) and (b) are a front view and a side view, respectively, of a primer inspection means according to another embodiment of the present invention;

FIG. 8 is a plan view of a front window glass intended for the pretreatment;

FIG. 9 is a flow chart showing the steps of a procedure for pretreatment for window glass adhesive coating; and

FIG. 10 is a side view of the pretreatment apparatus for the window glass adhesive coating (in a forward condition of an air cylinder).

### DETAILED DESCRIPTION OF THE PREFERRED EMBODIMENTS

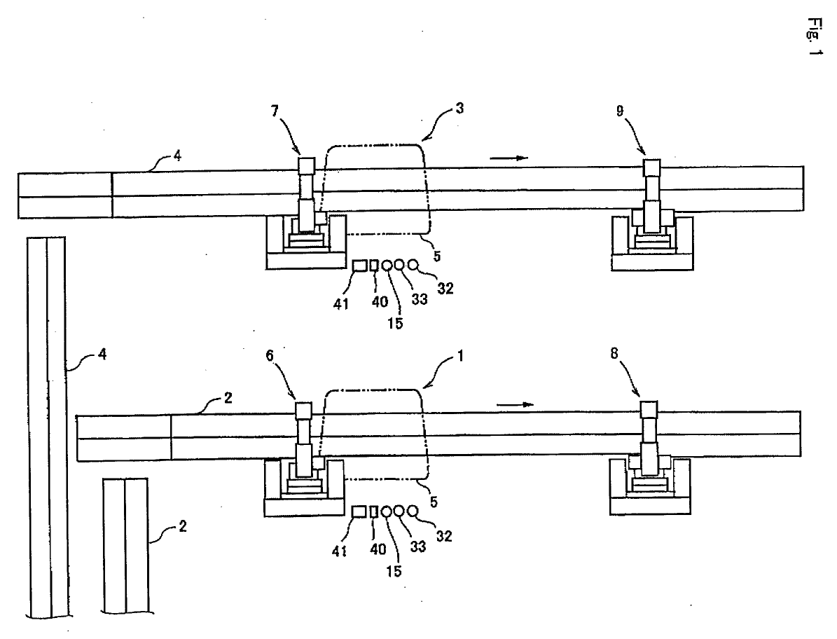

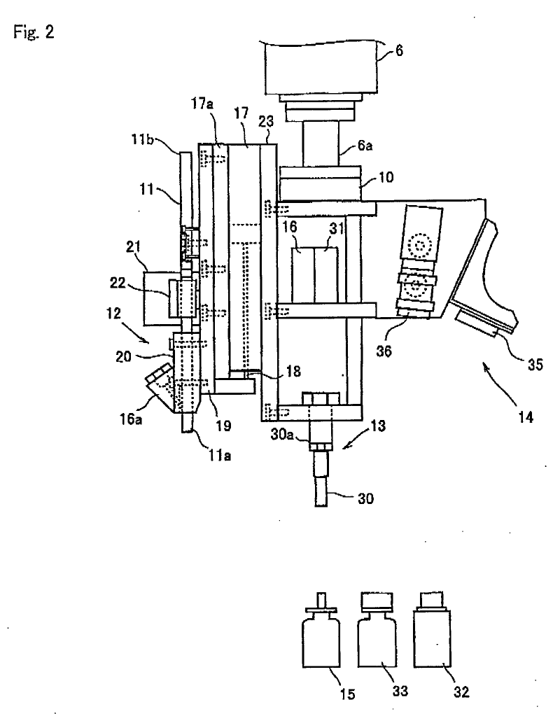

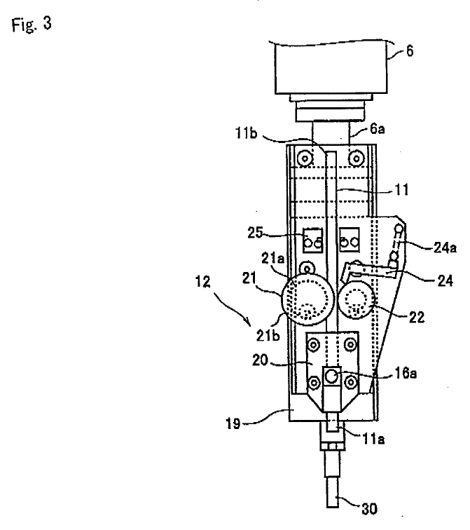

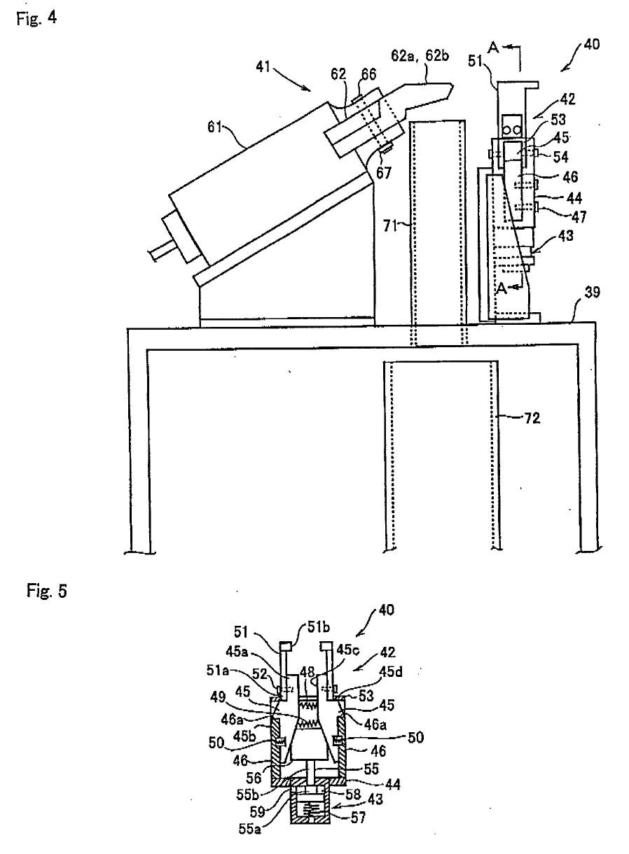

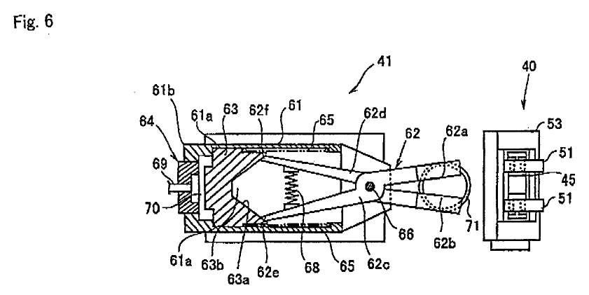

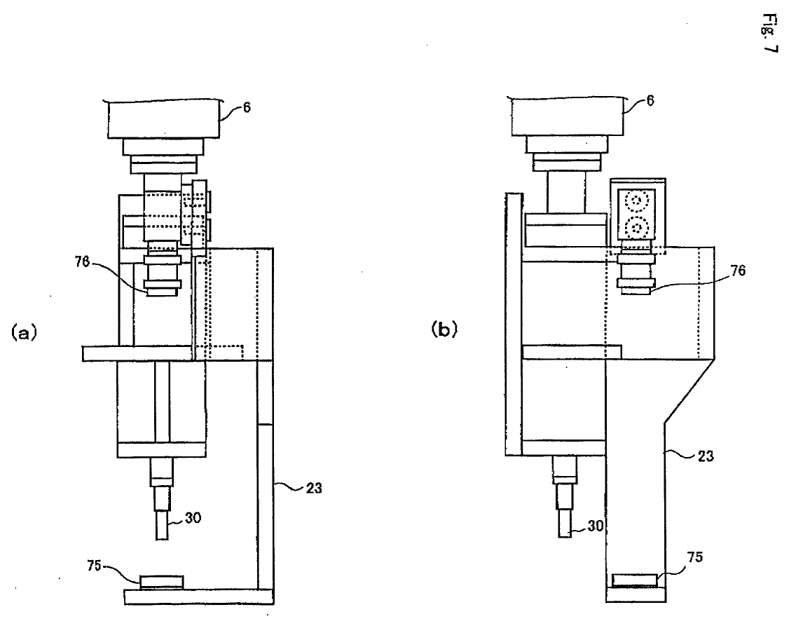

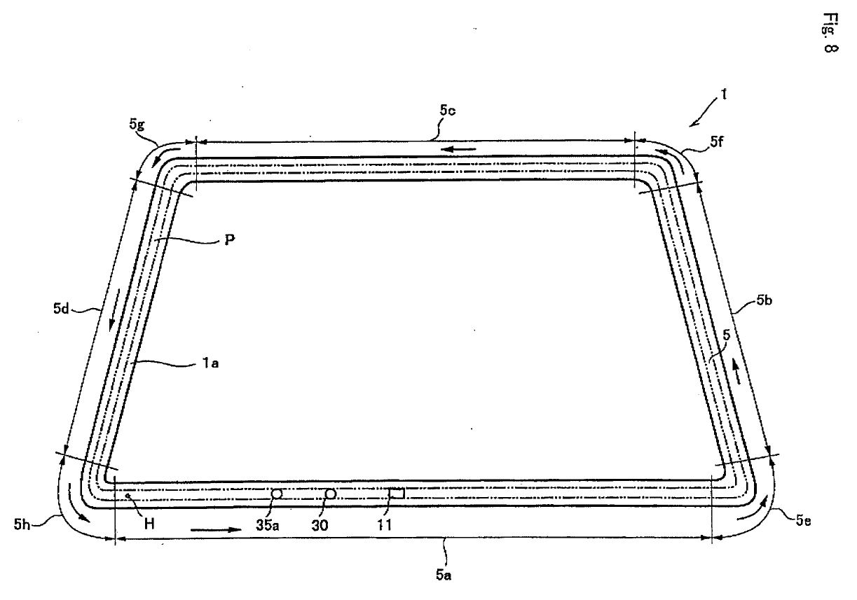

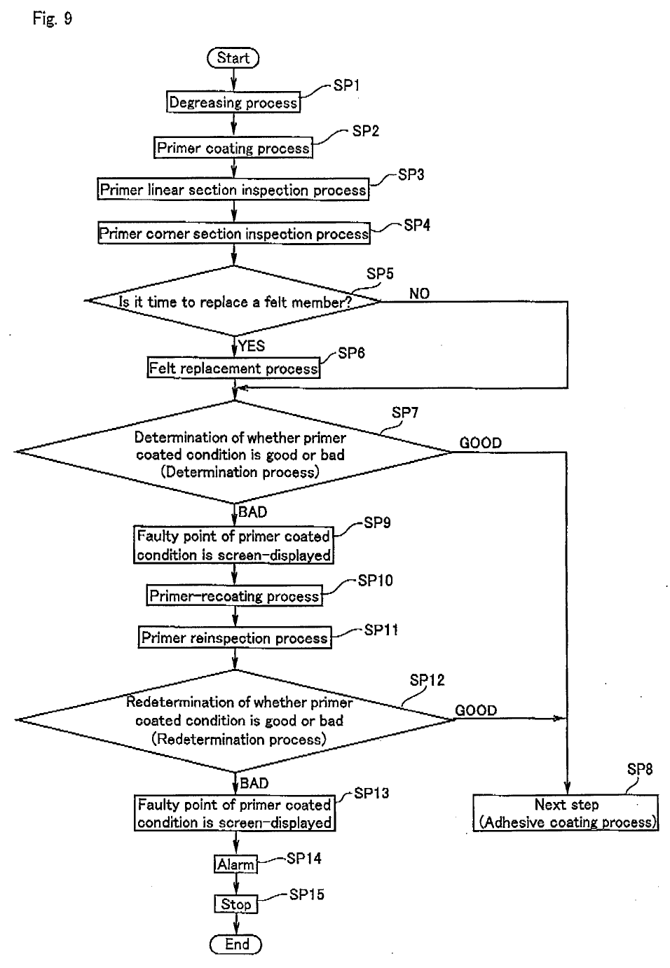

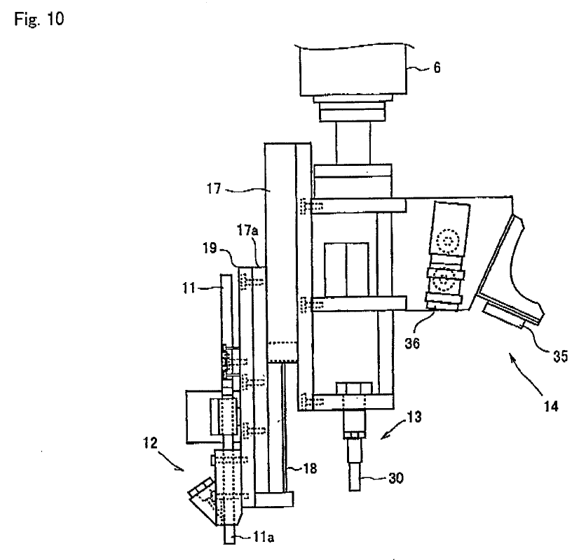

A preferred embodiment of the present invention will now be described with reference to the accompanying drawings. FIG. 1 is a view explaining a process to which a pretreatment apparatus for window glass adhesive coating and a method for the pretreatment according to the present invention are applied. FIG. 2 is a front view of the pretreatment apparatus for window glass adhesive coating according to the present invention and FIG. 3 is a side view of the same. FIG. 4 is a side view of a felt holding mechanism and a cutting mechanism and FIG. 5 is a cross-sectional view taken along line A-A of FIG. 4. FIG. 6 is a plan view of the felt holding mechanism and the cutting mechanism with a partial cross section. FIGS. 7(a) and 7(b) are a front view and a side view, respectively, of another embodiment of a primer inspection means. FIG. 8 is a plan view of a front window glass intended for the pretreatment. FIG. 9 is a flow chart showing the steps of a procedure for the pretreatment work for window glass adhesive coating. FIG. 10 is a side view of the pretreatment apparatus for window glass adhesive coating (in a forward condition of an air cylinder).

A pretreatment process to which a pretreatment apparatus for window glass coating and a method for the pretreatment according to the present invention is provided, as shown in FIG. 1, with a conveyor 2 for conveying a front window glass 1 from a pre-process and a conveyor 4 for conveying a rear window glass 3 from a pre-process. Each conveyor 2, 4 is provided with a primer coating robot 6, 7 for pre-treating an adhesive coating surface 5 of the window glasses 1, 3. Reference numerals 8, 9 are adhesive coating robots installed in a post-process for coating the adhesive coating surfaces 5, 5 of the pre-treated window glasses 1, 3 with an adhesive agent. Since these robots 8, 9 have the same structures as the robots 6, 7, the pretreatment apparatus of which the working object is the front window glass 1 will now be described.

As shown in FIG. 2, a connecting section 10 is detachably connected to an arm end 6a of the primer coating robot 6. The connecting section 10 is provided with a felt maintaining mechanism 12 for maintaining a felt member 11 through a base member 23, a primer coating means 13 for coating the adhesive coating surface 5 of the window glass 1, which is coated with a degreasing solution by the felt member 11, with a primer, and a primer inspection and determination means 14 for inspecting the primer coated condition coated by the primer coating means 13 and determining whether the coated condition is good or bad.

The felt member 11 consists of a felt formed in a square-bar shape and serves not only to remove foreign material (e.g., dust) and oil adhering to the adhesive coating surface 5 of the window glass 1, but also to coat the adhesive coating surface 5 with the degreasing solution. The degreasing solution is supplied from a degreasing solution storage tank 15 installed near the primer coating robot 6 to a front end section 11a of the felt member 11 through piping (not shown) and a valve 16. Reference numeral 16a is a degreasing solution supply section for supplying the front end section 11a of the felt member 11 with the degreasing solution.

The felt maintaining mechanism 12 is provided, as shown in FIGS. 2 and 3, in which a base member 19 fixedly secured to a slide plate 17a, which is attached to an end of a rod 18 of an air cylinder 17, is provided with a guide member 20 for guiding the front end section 11a of the felt member 11 in the desired direction, a knurl roll 21 adapted to hold and project the felt member 11, and a rotatable gear 22. The air cylinder 17 is fixedly secured to the base member 23 attached to the connecting section 10. In this manner, the felt member 11 is adapted to vertically move by the elevating movement of the air cylinder 17. Reference numeral 24 is a gear stop for rotating a gear 22 for one turn and preventing reverse rotation, and 25 is a sensor for detecting a rear end section 11b of the felt member 11.

The knurl roll 21 has a small diameter section 21a for supporting the felt member 11 from the horizontal direction and a large diameter section 21b for supporting the felt member 11 from the vertical direction. In order to stably hold the felt member 11, the outer peripheral surface of the small diameter section 21a is processed to provide knurls. The knurl roll 21 is fixedly secured to the base member 19. A gear section of the gear 22 disposed in a position facing the knurl roll 21 is adapted to engage with the gear stop 24 which is biased by a spring 24a toward the gear 22. In other words, the small diameter section 21a of the knurl roll 21 and the gear 22 hold the felt member 11 in position always controlling the movement of the felt member 11 in the horizontal and vertical direction. With this, the felt member 11 is prevented from swinging when coating with the degreasing solution.

The primer coating means 13 comprises, as shown in FIG. 2, a brush 30 and a valve 31 which are attached to the base member 23, and a primer storage tank 32 installed in the vicinity of the primer coating robot 6. The brush 30 is supplied with primer from the primer storage tank 32 through piping (not shown) and the valve 31. Disposed in the vicinity of the primer coating robot 6 is a steam generating tank 33 into which the brush 30 is inserted to prevent it from hardening using steam. Reference numeral 30a is a brush holder for holding the brush 30 and supplying the brush 30 with the primer.

The primer inspection and determination means 14 is formed in a reflection type as shown in FIG. 2 and is provided with a light projector 35 attached to the base member 23, and a camera 36 serving as a photoreceptor for receiving the reflected light emitted from the light projector 35. The camera 36 continuously takes pictures of the reflected light emitted from the light projector 35 for each frame and takes pictures of the adhesive coating surface 5 formed on the peripheral area of the front window glass 1 without omission.

The primer inspection and determination means 14 is also provided with a determination device (not shown) for calculating and storing the relationship between an imaging screen of the reflected light received by the camera 36 and a position of the reflected light on the adhesive coating surface 5 and determining whether the primer coated condition is good or bad, and a display device (not shown) for displaying the processing results of this determination device in a primer coated pattern and the like of the primer coating surface 5. The primer inspection and determination means 14 is disposed apart from and in the rear of the traveling direction of, the primer coating means 13.

When the light is emitted from the light projector 35 toward the adhesive coating surface 5 coated with the primer, the emitted light is reflected, as shown in FIG. 8, on a primer coated section P coated on the adhesive coating surface 5 and a ceramic section 1a in which the periphery of window glass is coated with a ceramic, and respectively enters the camera 36 as reflected light. In this manner, whether the primer coated condition is good or bad is determined by the amount of light in the ceramic sections 1a and the primer coated section P entering the camera 36.

In other words, the ceramic section 1a of the window glass periphery looks slightly darker than the primer coated section P. This slight difference of brightness is captured by the camera 36 and this image is digitalized by a determination means (not shown). For example, the window glass 1 is image-processed in white and the primer-coated section P in black to calculate the number of picture elements (pixels) of the primer coated section P. It is determined whether the primer coated condition is good or bad based on this calculated value. Since both the ceramic section 1a and the primer coated section P are black, the color red which can make a difference in brightness easy to distinguish is best suited for a light source for the light projector 35.

As shown in FIG. 1, disposed in the vicinity of the primer coating robot 6 are a felt holding mechanism 40 for enclosing the front end section 11a of the felt member 11 and a cutting mechanism 41 for cutting the front end section 11a of the felt member 11 to a predetermined length projected by a felt projection mechanism described later, in a condition in which the front end section 11a of the felt member 11 is enclosed in the felt holding mechanism 40.

The felt holding mechanism 40 comprises, as shown in FIGS. 4 and 5, a holding mechanism body 42 and a cylinder 43. Reference numeral 39 is a table on which the felt holding mechanism 40 and the cutting mechanism 41 are mounted. The holding mechanism body 42 has an outer cylinder 44 of a substantially horseshoe shape with a closed end in which guide members 46, 46 are disposed to slidably guide a pair of movable blocks 45, 45 in a horizontal direction. The guide members 46, 46 are fixedly secured to the outer cylinder 44 by bolts 47, 47. The guide members 46, 46 are formed in a square-pole shape of which the upper surface 46a serves as a slide surface for the movable block 45 and guides the movable block 45 in a horizontal direction.

The movable blocks 45, 45 are biased to come closer to each other from the action of springs 48, 49 and 50, and a lower end section 51a of a chuck claw 51 is fixedly secured to the upper end section 45a of each block 45. A step section 45b formed at a substantially central section engages a slide surface 46a of the guide member 46 to slidably move in a horizontal direction.

A stopper section 45c is formed by the surface facing the movable blocks 45, 45. The front end section 11a of the felt member 11 is held between the upper inner surfaces 51b, 51b of the chuck claw 51 in a condition in which each stopper section 45c is caused to touch (i.e., the movable blocks 45, 45 are in a closed condition). The slide surface 46a of the guide member 46 is set to have such a length that the movable block 45 slides on the slide surface 46a and the stopper sections 45c can touch each other.

Further, the upper section of the movable block 45 is provided with a step section 45d. A control member 54 of a horseshoe shape with an opening in the center touches the step section 45d and is fixedly secured to the outer cylinder 44 by a bolt 45 to control the movement of the movable block 45 in a vertical direction.

The cylinder 43 is disposed at the lower section of the holding mechanism body 42. A cylinder rod 55 passes through the bottom surface of the outer cylinder 44 to project inside the outer cylinder 44 and is provided at its front end with a pushing member 56. The pushing member 56 is biased in the projection direction by a spring, which is compressively installed within the cylinder 43, to push the movable blocks 45, 45, thereby causing the movable blocks 45, 45 to open against the contractive force of the springs 48, 49, and 50.

The basic end section 55a of the cylinder rod 55 is formed to provide a larger diameter than its central section 55b to act as a stopper and forms a cylinder chamber 58 even in a condition in which the pushing member 56 projects to the fullest extent (i.e., in a condition in which the movable blocks 45, 45 are opened). The cylinder chamber 58 is fed with air of a predetermined pressure via an air feed port 59 by operating a valve (not shown) to withdraw the cylinder rod 55 against the spring-back force of a spring 57, thereby becoming capable of opening the movable blocks 45, 45.

In this manner, the cylinder rod 55 is always biased by the spring 57 in the projecting direction and the movable blocks 45, 45 are caused to open by the pushing member 56 provided on the front end of the cylinder rod 55, wherein the chuck paws 51, 51 fixedly secured to the upper end section 45a of the movable blocks 45, 45 are also caused to open to form a gap into which the front end section 11a of the felt member 11 can be inserted.

In order to cause the chuck paws 51, 51 to hold the front end section 11a of the felt member 11, air of a predetermined pressure is fed through the air feed port 59 to the cylinder chamber 58 by operating the valve (not shown). Then, the pushing member 56 provided on the front end of the cylinder rod 55 retreats against the force of the spring 57, and the movable blocks 45, 45 are opened by the contractive force of the springs 48, 49 and 50, wherein the chuck paws 51, 51 hold the front end section 11a of the felt member 11 therebetween under the predetermined holding pressure. In this case, stopper sections 45c, 45c of the movable blocks 45, 45 are set to touch one another in advance in a position in which the upper inner surfaces 51b, 51b of the chuck paw 51 can receive the predetermined holding pressure.

In this manner, in the condition in which the front end section 11a of the felt member 11 is held between the chuck paws 51, 51, if the primer coating robot 6 is raised by a predetermined stroke in the vertical direction, the gear stop 24 is released, wherein a felt projection mechanism for projecting the felt member 11 to a predetermined length can be formed.

The cutting mechanism 41 comprises, as shown in FIGS. 4 and 6, a casing 61 of a substantially square, box-like shape of which the front end section is open, a scissor-like cutter 62, housed within the casing 61, of which the cutting edge sections 62a, 62b project outside the casing 61, a pushing member 63 slidably fitted into the casing 61 to open/close the cutting edge sections 62a, 62b of the cutter 62 by its forward and backward movement, an air supply section 64 for advancing the pushing member 63, and springs 65, 65 for moving the pushing member 63 backwards.

The cutter 62 is provided in such a manner that a cutter member 62c with the cutting edge section 62a formed at the front end and a cutter member 62d with the cutting edge section 62b formed at the front end are rotatably overlapped by a bolt-shaped axial member 66 passing through each central section to act like scissors. The axial member 66 also passes through the casing 61 and a screw section of the axial member 66 projecting from the casing is provided with a nut 67 to fixedly secure the cutter 62 to the casing 61. Installed in the vicinity of the rear end section of the cutter 62 is a spring 68 biased in the direction in which the rear end section 62e of the cutter member 62c moves away from the rear end section 62f of the cutter member 62d.

The pushing member 63 is formed in a substantially square-pole shape of which the surface facing the cutter 62 is provided with a recessed section 63b having a slope 63a. The pushing member 63 also touches step sections 61a, 61a formed on the inner wall of the casing 61 from the force of the springs 65, 65 disposed within the casing 61. The air supply section 64 is provided at the rear end section 61b of the casing 61 to supply a space 70, formed by the casing 61, the pushing member 63 and the like, with air of a predetermined pressure through an air supply pipe 69.

When the air of a predetermined pressure is fed into the space 70 through the air supply pipe 69, the pushing member 63 is caused to move forward against the force of the springs 65, 65. Then, since the rear end section 62e of the cutter member 62c and the rear end section 62f of the cutter member 62d move in the mutually approaching direction along the slope 63a of the pushing member 63, the cutter members 62c, 62d rotate around the axial member 66 to cross the cutting edge sections 62a, 62b.

Accordingly, if the front end section 11a of the felt member 11 is positioned between the cutting edge section 62a and the cutting edge section 62b, the front end section 11a can be cut. Reference numeral 71 is a guide cylinder for guiding the front end section 11a of the felt member 11 cut by the cutting mechanism 41 to a collection pail 72.

Thus, the felt holding mechanism 40 for enclosing the front end section 11a of the felt member 11, the felt projection mechanism for projecting the felt member 11 by a predetermined length in a condition in which the front end section 11a of the felt member 11 is enclosed by this felt holding mechanism 40, and the cutting mechanism 41 for cutting the front end section 11a of the felt member 11 projected by this felt projection mechanism form a felt regenerating mechanism.

The felt member 11 for removing dust adhering to the adhesive coating surface 5 to coat the adhesive coating surface 5 with the degreasing solution, the felt maintaining mechanism 12 for maintaining this felt member 11, the felt regenerating mechanism for replacing the felt member 11 maintained by this felt maintaining mechanism 12 constitutes the degreasing means.

In the case where the reflected light from the adhesive coating surface 5 coated with primer is captured with difficulty, as shown in FIG. 7, the primer inspection and determination means 14 can also be formed in a transmission mode by a light projector 75 mounted on the base member 23, and a camera 76 serving as a photoreceptor for receiving the light emitted from the light projector 75 through the adhesive coating surface 5 coated with the primer.

When the light is emitted from the light projector 75 toward the adhesive coating surface 5 coated with the primer, the emitted light transmits the primer coating section P coated on the adhesive coating surface 5 and the ceramic section 1a of the window glass periphery, as shown in FIG. 8, which enters the camera 76 as the transmitted light. In this manner, it is determined whether the primer coated condition is good or bad by the amount of light from the ceramic section 1a of the window glass periphery and the primer coated section P entering the camera 76.

In other words, the ceramic section 1a of the window glass periphery looks slightly brighter than the primer coated section P. This slight difference in brightness is captured by the camera 76, and this image is digitalized by a determination means (not shown). For example, the window glass 1 is image-processed in white and the primer coated section P is image-processed in black to calculate the number of picture elements (pixels) of the primer coated section P, thereby determining whether the primer coated condition is good or bad based on this calculated value.

Operation of the pretreatment apparatus for window glass adhesive coating as constructed above and the pretreatment method for window glass adhesive coating will now be described with reference to FIGS. 8 and 9 in which the front window glass 1 is intended for the pretreatment.

The adhesive coating surface 5 consists of, as shown in FIG. 8, the linear sections of four sides 5a, 5b, 5c and 5d and the corner sections of four points 5e, 5f, 5g and 5h. The adhesive coating surface 5 is formed on the ceramic section 1a.

In order to cope with the shape of the adhesive coating surface 5 of the front window glass 1, the primer coating robot 6 is taught in advance a working track of the front end section 11a of the felt member 11 needed in carrying out the pretreatment work, a working track of the brush 30 for primer coating, and a spot track of the light emitted by the light projector 35, respectively. The pretreatment work for adhesive coating is carried out by playing back the taught program.

First, in step SP1 (i.e., a degreasing process), a primer coating robot 6, which stands ready in an original position, is driven to locate the front end section 11a of the felt member 11 at a starting point H of the adhesive coating surface 5 of a front window glass 1 which has been conveyed and positioned by a conveyor 2 from a previous process. In this case, as shown in FIG. 10, by bringing an air cylinder 17 into a forward condition, the front end section 11a of the felt member 11 is caused to project from a brush 30 for primer coating so that the brush 30 does not interfere with the front window glass 1 and the like.

The front end section 11a of the felt member 11 is caused to touch the adhesive coating surface 5 and to go around the adhesive coating surface 5 formed on the edge section of the front window glass 1 while discharging a degreasing solution from the front end section 11a. In this manner, dust and oil adhering to the adhesive coating surface 5 are removed to allow the adhesive coating surface 5 to be coated with the degreasing solution. It is to be noted that, when the primer coating robot 6 stands ready in the original position, the brush 30 is inserted into a steam generating tank 33 to prevent it from hardening.

Next, in step SP2 (i.e., a primer coating process), after bringing the air cylinder 17 to a rear condition, the primer coating robot 6 is driven to locate the brush 30 at a starting point H of the adhesive coating surface 5. In this case, the brush 30 is caused to touch the adhesive coating surface 5 and to go around the adhesive coating surface 5 formed on the edge section of the front window glass 1 while discharging the primer from the brush 30. The primer is now coated on the adhesive coating surface 5 to form a primer coated section P.

Referring to the inspection of the primer coated condition of the linear sections 5a, 5b, 5c and 5e of the primer coating surface 5, in step SP3 (i.e., a primer linear section inspection process), the inspection is carried out simultaneously with the primer coating in step SP2. In other words, the spot 35a of the light emitted from the light projector 35 illuminates the linear section 5a of the adhesive coating surface 5. Likewise, the light spot 35a illuminates the second linear section 5b, the third linear section 5c, and the fourth linear section 5d along the arrow direction. In this case, the camera 36 takes pictures of the reflected light from the linear sections 5a, 5b, 5c and 5d for each consecutive frame.

In this case, the position of the adhesive coating surface 5 on the linear sections 5a, 5b, 5c and 5d illuminated by the light spot 35a, and an imaging screen of the light reflected by the linear sections 5a, 5b, 5c and 5d in this position and entering the camera 36, are stored. Then, by the position of the light spot 35a and the amount of the reflected light in this position, a primer coating pattern in the adhesive coating surface 5, which becomes data for determining whether the primer coated condition is good or bad, is created. The position of the light spot 35a is calculated by a detection value using a position transducer of the primer coating robot 6 and the physical relationship between the light projector 35 and the adhesive coating surface 5.

Referring to the inspection of the primer coated condition of the adhesive coating surface 5 on the corner sections 5e, 5f, 5g and 5h, in step SP4 (i.e., a primer corner section inspection process), the inspection is carried out simultaneously after completing the inspection of the linear sections 5a, 5b, 5c and 5d. Since the corner sections 5e, 5f, 5g and 5h are the points where the camera 36 cannot follow the working track of the primer coating means 13, it is not possible to carry out the inspection simultaneously with the primer coating, unlike the linear sections 5a, 5b, 5c and 5d.

First, the primer coating robot 6 is driven to locate the spot 35a of light emitted from the light projector 35 so that the spot 35a of light illuminates an entrance of the first corner section 5e on the adhesive coating surface 5. Then, the spot 35a of light emitted from the light projector 35 illuminates the first corner section 5e which will be coated with the primer, in the arrow direction. Likewise, the second corner section 5f, the third corner section 5g, and the fourth corner section 5h are illuminated along the arrow direction. In this case, the camera 36 takes pictures of the light reflected by the corner sections 5e, 5f, 5g and 5h of the adhesive coating surface 5 which will be coated with the primer for one continuous frame. The movement of the camera 36 between each corner section 5e, 5f, 5g and 5h is performed in the shortest distance and the moving speed can be set faster than the primer coating speed.

In this case, the position of the adhesive coating surface 5 on the corner sections 5e, 5f, 5g and 5h illuminated by the light spot 35a, and the imaging screen of the light reflected by the corner sections 5e, 5f, 5g and 5h in this position and entering the camera 36, are stored. Then, a primer coating pattern in the adhesive coating surface 5 which becomes data for determining whether the primer coated condition is good or bad is created by the position of the light spot 35a and the amount of reflected light in this position. It is to be noted that the position of the light spot 35a is calculated by a detection value of the primer coating robot 6 using the position transducer, and the physical relationship between the light projector 35 and the adhesive coating surface 5.

Next, in step SP5, the number of degreasing actions (i.e., the number of usages of the felt member 11) is counted. If it reaches a predetermined number, the front end section 11a of the felt member 11 is considered to be stained and must be replaced. The program then proceeds to step SP6 in which the front end section 11a of the felt member 1 is cut to be renewed. On the other hand, in the case where the number of degreasing actions does not reach the predetermined number, the program proceeds to step SP7 to determine whether the primer coated condition is good or bad.

In step SP6 (i.e., a felt replacement process), the primer coating robot 6 is driven to locate the front end section 11a of the felt member 11 between the chuck paws 51 and 51. Air of a predetermined pressure is then supplied to the cylinder chamber 58 by operating a valve (not shown). In this manner, the upper inner surfaces 51b, 51b of the chuck paws 51, 51 contain the front end section 11a of the felt member 11 under the predetermined holding pressure.

In the condition in which the front end section 11a of the felt member 11 is contained by the chuck paws 51, 51, the primer coating robot 6 is raised in the vertical direction by a predetermined distance. Then, the felt member 11 is caused to project by a predetermined length by the action of the felt projection mechanism. Further, the primer coating robot 6 is driven to locate a cutting position of the felt member 11 between the cutting edge sections 62a, 62b of the cutting mechanism 41. When air of a predetermined pressure is supplied into the space 70, the cutter members 62c, 62d rotate around the axial member 66, wherein the front end section 11a of the felt member 11 is cut by the cutting edge sections 62a, 62b to renew the front end section 11a of the felt member 11.

Next, in step SP7 (i.e., a determination process), it is determined whether the primer coated condition is good or bad from the primer coated pattern, coated on the adhesive coating surface 5 of the front window glass 1, obtained in the primer inspection process. If the determination result is good, the program proceeds to step SP8, in which the front window glass 1 is conveyed to the next adhesive coating process. On the other hand, if the determination result is bad, the program proceeds to step SP9.

Next, in step SP9, a faulty point of the primer coated condition is displayed from the primer coated pattern obtained in the primer inspection.

Further, in step SP10, the primer coating robot 6 is driven to recoat the faulty point of the primer coated condition with primer (i.e., a primer recoating process). Just like in step SP2, the brush 30 is located at the starting point H of the adhesive coating surface 5. The brush 30 is then caused to touch the adhesive coating surface 5 and go around the adhesive coating surface 5 of the front window glass 1 while discharging the primer from the brush 30, thereby recoating the adhesive coating surface 5 with primer.

Next, in step SP11, the primer linear section inspection and the primer corner section inspection are carried out (i.e., a primer re-inspection process) in the same manner as in step SP3 and step SP4, and in step SP12, determination like in step SP7 is made (i.e., a re-determination process). If the determination result is good, the program proceeds to step SP8, wherein the front window glass 1 is conveyed to the next adhesive coating process. On the other hand, if the determination result is bad, the program proceeds to step SP13.

In step SP13, like step SP9, a faulty point of the primer coated condition is displayed from the primer coated pattern obtained in the primer inspection. In step SP14, an alarm is given and in step SP15, the pretreatment work is stopped. Thus, the pretreatment work for window glass adhesive coating using the primer coating robot 6 is completed. After this, an operator amends the primer coated condition by hand.

In the embodiments of the present invention, as a procedure for the pretreatment, the degreasing process for the adhesive coating surface 5 is carried out first and the, the primer is coated on the degreased adhesive coating surface 5. However, the inspection of the primer coated condition of the adhesive coating surface 5 on the linear sections 5a, 5b, 5c and 5d is carried out simultaneously with the primer coating, while the inspection of the primer coated condition of the primer coating surface 5 on the corner sections 5e, 5f, 5g and 5h is carried out simultaneously after completing the inspection of the linear sections 5a, 5b, 5c and 5d.

Referring to the pretreatment procedures, for example, the degreasing process for the adhesive coating surface 5 is carried out first and then, the primer is coated on the degreased adhesive coating surface 5, wherein the inspection of the primer coated condition can also be carried out in the order of the linear section 5a, the corner section 5e, the linear section 5b, the corner section 5f, the linear section 5c, the corner section 5g, the linear section 5d, and the corner section 5h of the adhesive coating surface 5.

Further, the degreasing process for the adhesive coating surface 5 is carried out and then the primer is coated on the degreased adhesive coating surface 5. However, the inspection of the primer coated condition of the adhesive coating surface 5 on the linear sections 5a, 5b, 5c and 5d is carried out simultaneously with the primer coating, but the inspection of the primer coated condition of the adhesive coating surface 5 on the corner sections 5e, 5f, 5g and 5h can also be carried out immediately after coating each corner of 5e, 5f, 5g and 5h with the primer.

### EFFECTS OF THE INVENTION

As described above, according to the first aspect of the present invention, one robot is provided with a degreasing means, a primer coating means, and a primer inspection means. With this arrangement, degreasing, primer coating, inspection of the primer coated condition, and determination of the inspection results can be carried out by such a single robot and as a result, this contributes to lowering the number of man-hours.

According to the second aspect of the present invention, removal of dust and oil adhering to the adhesive coating surface and coating of the degreasing solution on the adhesive coating surface can be surely performed by the felt member. In addition, since the felt regenerating mechanism is provided, the felt member stained with dust and oil after repeated use can be readily regenerated.

According to the third aspect of the present invention, the felt regenerating mechanism comprises the felt holding mechanism for holding the front end section of the felt member therebetween, the felt projection mechanism for projecting the felt member by a predetermined length, and the cutting mechanism for cutting the front end section of the projected felt member. With this arrangement, only the front end section of the felt member stained with dust, oil and the like can be automatically cut to readily and be quickly regenerated into a new felt member.

According to the fourth aspect of the present invention, degreasing, primer coating, inspection of the primer coated condition, and determination of whether the primer coated condition is good or bad based on the inspection results, can be carried out, and this can ensure the quality assurance of the pretreatment for window glass adhesive coating.

According to the fifth aspect of the present invention, the inspection of the primer coated conditions of the linear sections (i.e., four sides) is conducted simultaneously with the primer coating, in other words, is conducted coating with the primer, while the inspection of the primer coated conditions at the corner sections (i.e., four places) is conducted simultaneously after completing the inspection of the straight sections (four sides). Thus, it is possible not only to increase the inspection speed, but also to efficiently conduct the inspection of the primer coated conditions.

According to the sixth aspect of the present invention, in the case where the primer coated condition is determined to be bad, recoating of the faulty points, re-inspection of the primer recoated condition, and re-determination on whether the primer coated condition is good or bad based on the re-inspection results are carried out, and this can ensure the quality assurance of the pretreatment for window glass adhesive coating.

### INDUSTRIAL APPLICABILITY

Since one robot is provided with a degreasing means, a primer coating means, and a primer inspection and determination means, the degreasing process, the primer coating process, and the inspection and determination process for the primer coated condition can be fully automated by such a single robot and as a result, it is possible to constitute a pretreatment apparatus for window glass adhesive coating which contributes to the reduction of the number of man-hours and occupies little space, and a method for the pretreatment.

1. An apparatus for conducting pretreatment including primer coating an adhesive coating surface of window glass using a robot comprising:
a degreasing means for removing dust and oil adhering to the adhesive coating surface and coating the adhesive coating surface with a degreasing solution;
a primer coating means for coating the adhesive coating surface with primer, after that surface has been degreased by the degreasing means; and
a primer inspection and determination means for inspecting the primer coated condition provided by the primer coating means to determine whether the primer coating condition is good or bad,
wherein the primer inspection and determination means carries out inspection of the primer coated condition of linear sections simultaneously with coating by the primer coating means, and thereafter carries out inspection of the primer coated condition of corner sections.

2. The pretreatment apparatus for window glass adhesive coating according to claim 1, wherein the degreasing means comprises: a felt member for removing dust and oil adhering to the adhesive coating surface and coating the adhesive coating surface with the degreasing solution; a felt maintaining mechanism for maintaining the felt member; and a felt regenerating mechanism for regenerating the felt member maintained by the felt maintaining mechanism.

3. The pretreatment apparatus for window glass adhesive coating according to claim 2, wherein the felt regenerating mechanism comprises: a felt holding mechanism for containing a front end section of the felt member; a felt projection mechanism for projecting the felt member to a predetermined length in a condition in which the front end section of the felt member is contained by the felt holding mechanism; and a cutting mechanism for cutting the front end section of the felt member projected by the felt projection mechanism.

4. A pretreatment method for coating an adhesive coating surface of window glass with primer comprising the steps of:
degreasing for removing dust and oil adhering to the adhesive coating surface and for coating the adhesive coating surface with a degreasing solution;
coating the adhesive coating surface, processed in the degreasing step, with primer;
inspecting the primer coated condition coated in the primer coating step; and
determining whether the primer coated condition is good or bad based on the inspection results of the primer inspection step,
wherein in the primer inspection step, inspection of the primer coated condition of linear sections is carried out simultaneously with coating in the primer coating step, thereafter inspection of the primer coated condition of corner sections is carried out, and whether the primer coated condition is good or bad is determined based on the inspection results of the primer inspection step.

5. (canceled)

6. The pretreatment method for window glass adhesive coating according to claim 4, wherein, in the case where the primer coated condition is determined to be bad in the determination step, the method comprises the steps of: recoating a faulty point with primer; re-inspecting the primer recoated condition; and re-determining whether the primer coated condition is good or bad based on the re-inspection results.
